(19) United States
(12) Patent Application Publication
(10) Pub. No.: US 2013/0001499 A1
(43) Pub. Date: Jan. 3, 2013

(54) Compressive Structure for Enhancing Contact of Phase Change Material Memory Cells

(75) Inventors: Matthew J. Breitwisch, Armonk, NY (US); Chung H. Lam, Armonk, NY (US); Alejandro G. Schrott, Armonk, NY (US)

(73) Assignee: International Business Machines Corporation, Armonk, NY (US)

(21) Appl. No.: 13/171,210

(22) Filed: Jun. 28, 2011

(51) Int. Cl. H01L 45/00; H01L 21/06; H01L 21/62

(52) U.S. Cl. 257/3; 438/381; 438/102; 257/E21.068; 257/E21.52; 257/E45.002

(57) ABSTRACT

A process for manufacturing a PCM device comprises forming a dielectric, producing a via in the dielectric starting at an area on the surface of the dielectric by forming a via opening in the area and extending the opening into the dielectric toward and then terminating at an electrode comprising a first electrode in the dielectric. We form a spacer layer contiguous with the side walls of the via and fill the via with a PCM. We then remove the surface of the dielectric to leave a PCM cusp at the opening of the via, cap the PCM cusp with a low density capping film; densify the PCM and capping film to obtain a high density capping film that exerts compressive pressure on the high density PCM in a direction toward the first electrode to enhance electrical contact between the PCM and the first electrode.

### FIELD OF THE INVENTION

The field of the invention comprises phase change memory cells, a process for their manufacture, and products made by such process.

### BACKGROUND OF THE INVENTION

There are two major categories of computer memory: non-volatile memory and volatile memory. Non-volatile memory does not require constant input of energy in order to retain information whereas volatile memory does. In non-volatile memory devices, the memory state can be retained for days to decades without power consumption. Examples of non-volatile memory devices comprise Read Only Memory (ROM), Flash Electrical Erasable Read Only Memory, Ferroelectric Random Access Memory (FRAM), Magnetic Random Access Memory (MRAM), and Phase Change Memory.

Examples of volatile memory devices comprise Dynamic Random Access Memory (DRAM) and Static Random Access Memory (SRAM); where DRAM requires the memory element to be constantly refreshed while SRAM requires a constant supply of energy to maintain the state of the memory element.

Phase change materials (PCM) are poised to play a fundamental role in new solid state phase change memory and storage devices. In order to comply with the requirements imposed by the scaling road map, it is expected that the memory cells will be of the confined type, where the PCM is deposited via chemical vapor deposition (CVD) or atomic layer deposition (ALD) processes into a predefined cavity.

Phase change memory involves manipulating specific materials (PCM's) into different phases to store information. Each phase exhibits different electrical properties which enables the PCM to store information. The amorphous and crystalline phases are typically two phases used for bit storage (1's and 0's) since they have detectable differences in electrical resistance. Specifically, the amorphous phase has a higher resistance than the crystalline phase.

Chalcogens comprise non-metallic Group VIA elements (Periodic Table Group VIA [IUPAC Form]) commonly used to form phase change materials, i.e., compounds or alloys (also referred to herein as “a combination or combinations”) with another element, and sometimes referred to as “chalcogenide” PCM's. Selenium (Se) and tellurium (Te) are the two most common chalcogens used to produce these compounds or alloys (“combinations”).

Exposing the PCM to laser or electrical pulses of different intensity and duration repeatedly switches the PCM between crystalline and amorphous phases. A short intense pulse melts the material, which is subsequently quenched into the amorphous phase; a less intense pulse heats the material above the crystallization temperature and reverses the process.

An important step to obtain optimal performance of PCM cells is to densify the PCM after deposition via a rapid thermal annealing or laser annealing process. The latter steps may have unintended consequences due to action of capillary forces at the PCM/spacer interface of the cell during the densification process. This could produce a detachment of the PCM at the bottom contact of the PCM cell.

### RELATED ART

The following patents and published applications provide examples of the state of the art of PCM memory cells:
Breitwisch, et al., United States Patent Application Publication 2010/0078621;
Horii, et al., United States Patent Application Publication 2010/0081263, and U.S. Pat. No. 7,767,491;
Kang, United States Patent Application Publication 2009/0206317;
Chen, United States Patent Application Publication 2009/0189140;
An et al., U.S. Pat. No. 7,777,212;
Chae, et al., U.S. Pat. No. 7,772,101;
Shin, et al. U.S. Pat. No. 7,777,214.

### SUMMARY OF THE INVENTION

The present invention comprises structures, articles of manufacture, processes and products produced by the processes that address the foregoing needs, and provides substantially optimal performance PCM cells.

We form a PCM cell by depositing a PCM in a via opening in a dielectric layer lined with spacer material to form a PCM/spacer interface that extends into the dielectric layer for a distance and terminates at an electrode contact. We then remove part of the dielectric layer at the opening to leave a small part of the PCM to extend out of the opening and form a cusp, and then place a low density capping film on the dielectric layer to envelop the cusp. We densify the PCM after deposition via a rapid thermal annealing or processing (RTP) to substantially prevent a diffusion process from taking place in the selecting devices. The thermal processing also densifies the low density capping film causing it to compress the PCM in the via against the electrode contact. This densification substantially avoids or minimizes detachment of the PCM at the electrode contact of the PCM cell.

The low density capping film could be for example Si-Nitride, Al-Nitride, Boron Nitride all deposited at low temperature in the range of about 150 to about 300 Degree C.

Rapid thermal annealing or processing (RTP) refers to a semiconductor manufacturing process which heats silicon wafers to high temperatures (up to about 1,200° C. or greater) on a timescale of several seconds or even millisecond range. During cooling, however, wafer temperatures must be brought down slowly so they do not break due to thermal shock. Such rapid heating rates are often attained by high intensity lamps or lasers. The latter are more appropriate for ultra-fast heating. These processes are used for a wide variety of applications in semiconductor manufacturing including dopant activation, thermal oxidation, metal reflow and chemical vapor deposition.

Stated otherwise, RTP comprises (a) a pre-anneal step which includes heating to a temperature and for a period sufficient to preheat the wafer so as to reduce thermal shock due to a main annealing step, (b) the main annealing step being at a temperature and for a period sufficient to provide the densification of the PCM and the capping film, and (c) a post-anneal step carried out at a temperature and for a period sufficient to relieve stresses which may result from the main-annealing step.

In one embodiment RTP comprises, in succession, exposure of the device in a pre-anneal step at temperatures ranging from about 400.degrees to about 500.degrees C. for a period of from about 20 to about 40 seconds, the main annealing step at a peak temperature within a range of from about 650.degrees to about 850.degree C. for a period of from about 5 to about 2000 milliseconds, and the post-anneal step at temperatures ranging from about 400.degrees to about 500.degrees C. for a period of from about 25 to about 35 seconds, followed by cool down at a rate of from about 5 degrees to about 10 degrees C. per second, in either a nitrogen, oxygen, Ar, or He atmosphere

### BRIEF DESCRIPTION OF THE DRAWINGS

The accompanying drawings are not necessarily drawn to scale but nonetheless set out the invention, and are included to illustrate various embodiments of the invention, and together with this specification also serve to explain the principles of the invention. These drawings comprise various Figures that ilustrate a compressive strucutre for enhancing contacts in phase change material memory cells.

FIGS. 1 to 4 comprise side elevations in cross-section illustrating PCM devices in various stages of manufacture according to the invention and inherently show steps in a process for manufacturing these PCM devices.

FIG. 5 comprises a side elevation in cross-section illustrating the additional steps used to convert these PCM devices into PCM cells.

### DETAILED DESCRIPTION OF THE INVENTION

To achieve the foregoing and other advantages, and in accordance with the purpose of this invention as embodied and broadly described herein, the following detailed description comprises disclosed examples of the invention that can be embodied in various forms.

The specific processes, compounds, compositions, and structural details set out herein not only comprise a basis for the claims and a basis for teaching one skilled in the art to employ the present invention in any novel and useful way, but also provide a description of how to make and use this invention. Not only do the written description, claims, abstract of the disclosure, and the drawings that follow set forth various features, objectives, and advantages of the invention and how they may be realized and obtained, but these features, objectives, and advantages will also become apparent by practicing the invention.

We obtain optimal performance of PCM by densification of the PCM after deposition via a rapid thermal annealing or laser annealing process where the PCM is positioned in a via formed in a dielectric material lined with a spacer material. The latter steps may have unintended consequences due to action of capillary forces at the PCM/spacer interface during the densification process, which could produce a detachment of the PCM at the bottom contact in the via which comprises an electrode.

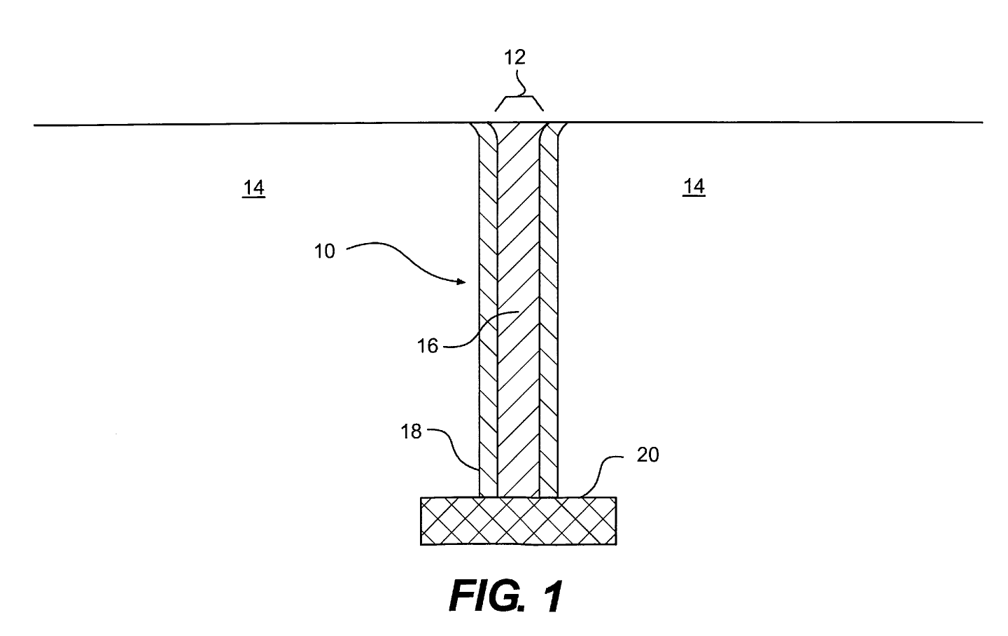

In order to preserve a robust and reliable bottom electrical contact during the densification process, i.e., enhancing this electrical contact, a low density layer or capping film is coated on a cusp we form in the profile of the exposed PCM following a chemical mechanical polishing step, and capping the exposed PCM. During densification, the capping film also becomes densified and will exert a compressive force on the PCM in a direction toward the bottom contact or electrode which substantially eliminates or minimizes detachment of the PCM at the bottom contact Referring to FIG. 1, the structure 10 comprises a dielectric layer 14 having a tubular via opening 12 with a spacer layer 18 contiguous with, and substantially extending around the circumference of the outside wall of via 12. In one embodiment, dielectric 14 comprises silicon oxide, silicon nitride, silicon oxy-nitride, aluminum oxide and/or titanium oxide. Spacer layer 18 may comprise one of SIC, SiN, SiCOH, TiO₂ and Ta₂Oₛ. or combinations thereof. The spacer layer 18 is introduced to improve the wetting of the phase change material (PCM) to be deposited, and to control the heat transfer during setting, and it is selected to fit the desired properties of the particular PCM/spacer interface.

After forming spacer 18 we introduce PCM 16 into via 12 by either a chemical vapor deposition process (CVD) or atomic layer deposition process (ALD) known in the art and chemical deposition. This is followed by Chemical Mechanical Polishing (CMP). which has the role of removing the surface part of the spacer and planarizing the surface of the spacer.

The phase change material 16 comprises a material having two stable states. For example, the phase change material may comprise chalcogenide elements such as tellurium (Te) and/or selenium (Se). In addition, the phase change material may further comprise compounds or alloys (“combinations”) of germanium (Ge), antimony (Sb), bismuth (Bi), palladium (Pd), tin (Sn), silver (Ag), arsenic (As), sulfur (S), silicon (Si), phosphorus (P), oxygen (O) and/or nitrogen (N). For example, the phase change material may comprise Ge—Sb—Te; As—Sb—Te; As—Ge—Sb—Te; Sn—Sb—Te; Ag—In—Sb—Te; In—Sb—Te; a compound layer of a Group VA element (IUPAC Form), antimony (Sb) and tellurium (Te); a compound layer of a chalcogen, antimony (Sb) and tellurium (Te); a compound layer of a Group VA element (IUPAC Form), antimony (Sb) and selenium (Se); and/or a compound layer of a chalcogen (with the exception of selenium (Se)), antimony (Sb) and selenium (Se).

In one embodiment, “chalcogenide” PCM's, comprise for example, Ge₂Sb₂Te₅, SbTe, and In₂ Se₃. The so-called Ge—Sb—Te (GST) materials, however, are the PCM's of choice for optical memory devices. They are also the leading candidates for a new generation of non-volatile electronic memory.

Via 12 and spacer 18 extend toward and terminate at electrode 20 which may comprise at least one of titanium (Ti), titanium nitride (TiN), tantalum nitride (TaN), molybdenum nitride (MoN), niobium nitride (NbN), titanium silicon nitride (TiSiN), titanium aluminum nitride (TiAlN), titanium boron nitride (TiBN), zirconium silicon nitride (ZrSiN), tungsten (W), tungsten nitride (WN), graphite, carbon nitride (CN), tungsten silicon nitride (WSiN), tungsten boron nitride (WBN), zirconium aluminum nitride (ZrAlN), molybdenum silicon nitride (MoSiN), molybdenum aluminum nitride (MoAlN), tantalum silicon nitride (TaSiN), tantalum aluminum nitride (TaAlN), titanium oxynitride (TiON), titanium aluminum oxynitride (TiAlON), tungsten oxynitride (WON) and tantalum oxynitride (TaON). Electrode 20 may be formed by a deposition process such as a physical vapor deposition (PVD) method, a CVD method or an ALD method and a patterning process known in the art. We form the electrode 20 prior to forming the via 12 by methods know in the art, such as patterning an electrode layer, depositing the electrode in the resulting patterned area, followed by building the electrode layer to a greater thickness before forming the via 12.

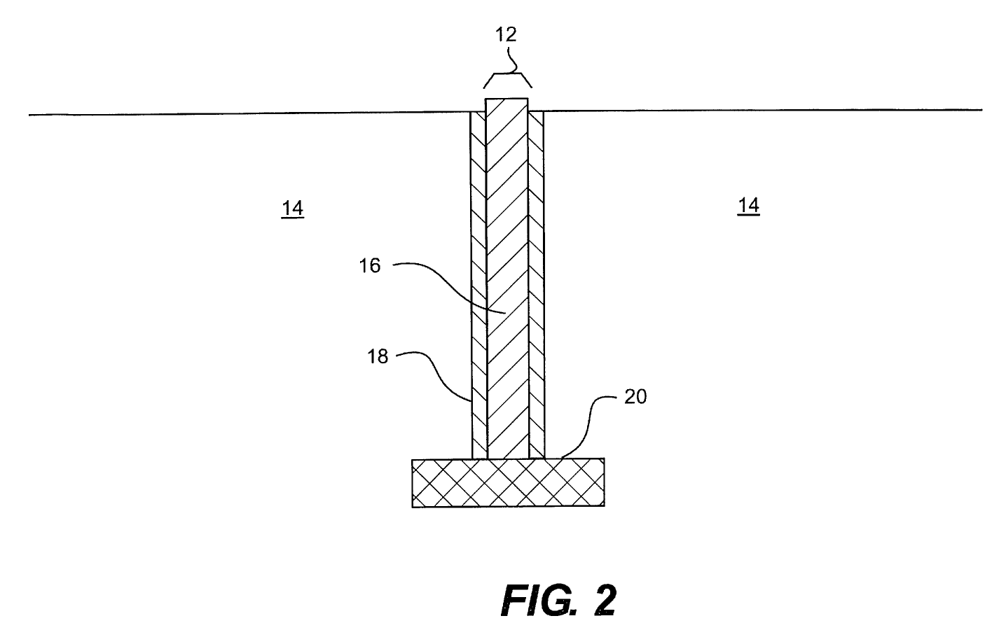

FIG. 2 illustrates a process for recessing dielectric 14 after deposition by means of CMP, the latter also removing the spacer 18 at the surface, exposing the silicon oxide. In order to obtain a cusp on the PCM, a timed wet process using HF is utilized. The latter does not attack the PCM but recesses the silicon oxide field, leaving a PCM cusp.

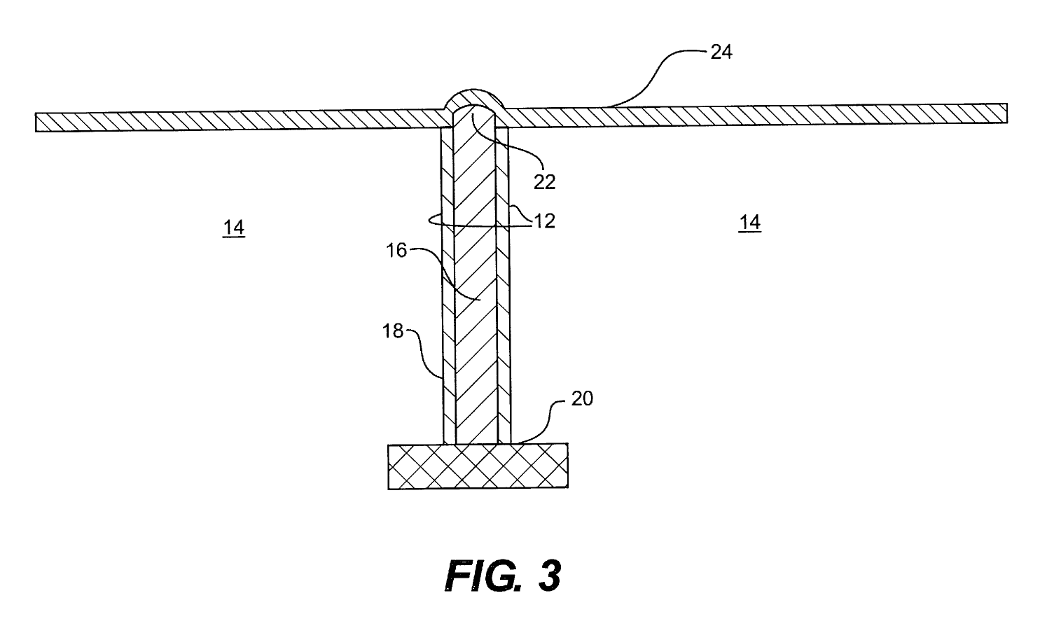

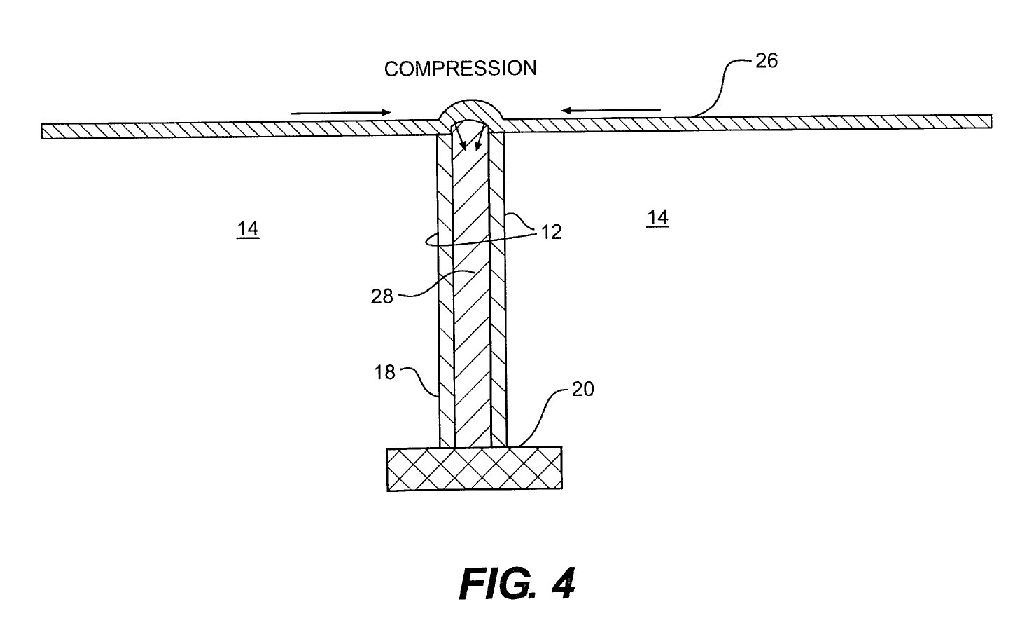

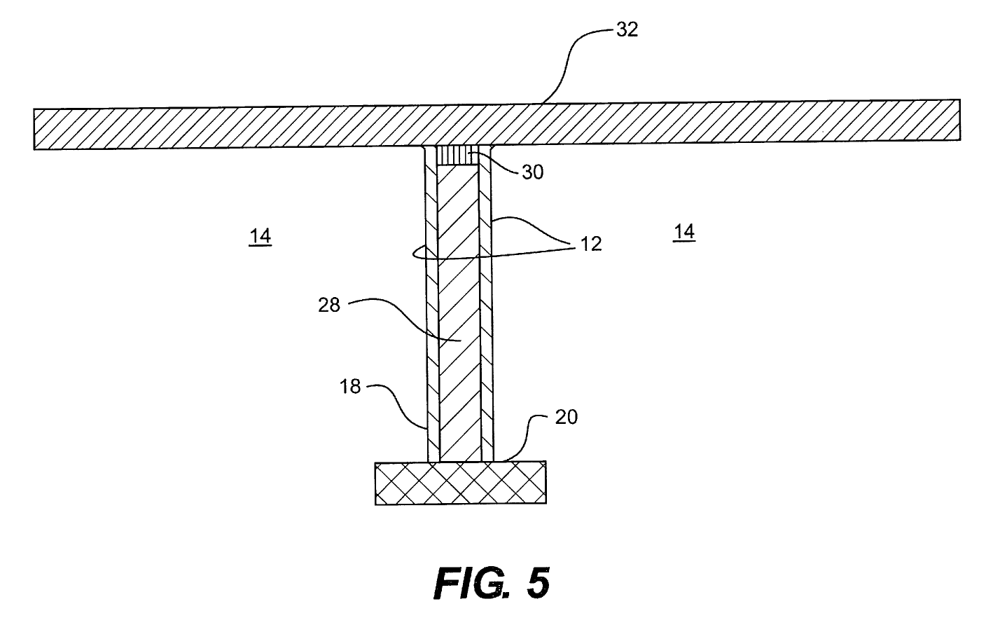

FIG. 3 illustrates the next step in the process comprising applying a low density film 24 to coat cusp 22 and extend outwardly from cusp 22 to also coat the surface of dielectric 14. We then obtain optimal performance of the PCM 16 by densification using rapid thermal processing via a capacitor discharge quartz lamp or laser pulse, densifying the film 24, and the PCM to high density PCM 28 as illustrated in FIGS. 4 and 5. For this process to be effective, the recess is programmed such that, the volume of the PCM cusp 22 must be smaller than volume of the PCM inside the via. This reduces the volume forces arising from the cusp 22 which may counterbalance the pressure effect of the densification of film 24, which aims at attaining a density within 5% of their sintered value: Si-Nitride (˜3.3 g/cc), Al-Nitride˜(3.2 g/cc), B Nitride (˜1.9 g/cc).

Low density film 24 becomes operatively associated with cusp 22 in the coating process so that PCM 16 densification to high density PCM 28 via rapid thermal processing also converts low density film 24 to high density film 26 that in turn exerts compressive forces on PCM 16 in a direction toward electrode 20 as illustrated in FIG. 4. These compressive forces substantially eliminate or minimize detachment of PCM 16 from electrode 20 during rapid thermal annealing or laser annealing. The low density films, are not restricted to but preferably comprise dielectrics, and are usually formed by physical or chemical deposition usually at low temperatures. The latter prevents surface diffusion and thus condensation of the film.

In FIG. 5 we illustrate removal of high density film 26 by CMP to expose dielectric 14 and the top part of the PCM material. FIG. 5 also illustrates the application of an electrode 30 operatively associated with high density PCM 28 at the opening of via 12. The role of this electrode is to prevent inter-diffusion of PCM/TEC (top electrical contact) materials while being electrically conductive. We then construct a top electrical contact (TEC) 32 by means of a Back End Of Line (BOEL) processes well known to those skilled in the art.

Throughout this specification, and abstract of the disclosure, the inventors have set out equivalents, of various materials as well as combinations of elements, materials, compounds, compositions, conditions, processes, structures and the like, and even though set out individually, also include combinations of these equivalents such as the two component, three component, or four component combinations, or more as well as combinations of such equivalent elements, materials, compositions conditions, processes, structures and the like in any ratios or in any manner.

Additionally, the various numerical ranges describing the invention as set forth throughout the specification also includes any combination of the lower ends of the ranges with the higher ends of the ranges, and any single numerical value, or any single numerical value that will reduce the scope of the lower limits of the range or the scope of the higher limits of the range, and also includes ranges falling within any of these ranges.

The terms “about,” “substantial,” or “substantially” as applied to any claim or any parameters herein, such as a numerical value, including values used to describe numerical ranges, means slight variations in the parameter. In another embodiment, the terms “about,” “substantial,” or “substantially,” when employed to define numerical parameter include, e.g., a variation up to five per-cent, ten per-cent, or 15 per-cent, or somewhat higher.

All scientific journal articles and other articles, including internet sites, as well as issued and pending patents that this written description or applicants' Invention Disclosure Statements mention, including the references cited in such scientific journal articles and other articles, including internet sites, and such patents, are incorporated herein by reference in their entirety and for the purpose cited in this written description and for all other disclosures contained in such scientific journal articles and other articles, including internet sites as well as patents and the references cited therein, as all or any one may bear on or apply in whole or in part, not only to the foregoing written description, but also the following claims, and abstract of the disclosure.

Although the inventors have described their invention by reference to some embodiments, other embodiments defined by the doctrine of equivalents are intended to be included as falling within the broad scope and spirit of the foregoing written description, and the following claims, and abstract of the disclosure.

We claim:

1. A process for manufacturing a PCM device comprising forming a dielectric, producing a via in said dielectric starting at an area on the surface of said dielectric by forming a via opening in said area and extending said opening into said dielectric toward and then terminating at an electrode comprising a first electrode in said dielectric;
filling said via with a PCM so that said PCM is contiguous with said spacer layer;
enhancing electrical contact between said PCM and said first electrode during subsequent densification of said PCM comprising;
removing the surface of said dielectric that extends around said via opening in said dielectric to leave a PCM cusp at the opening of said via, said cusp extending above the surface of said dielectric, wherein the volume of the cusp is smaller than the volume inside the via;
capping said PCM cusp with a low density capping film;
densifying said PCM and said low density capping film by a rapid thermal process to produce a high density PCM and a high density capping film whereby said high density capping film exerts compressive pressure on said high density PCM in a direction toward said first electrode to enhance electrical contact between said PCM and said first electrode.

2. The process of claim 1 wherein a spacer layer that extends around and is contiguous with the side walls of said via is formed prior to said filling-in with said PCM.

3. The process of claim 1 comprising converting said PCM device into a PCM cell comprising removing said high density capping film and said PCM cusp to leave an area of exposed high density PCM at said via opening in said dielectric, forming a second electrode on said exposed high density PCM in said dielectric, and forming a TEC layer over said second electrode and said dielectric adjacent said second electrode.

4. The process of claim 2 wherein said spacer layer is selected from one of SiO, SiN, SiCOH, TiO₂ and Ta₂Oₛ, and combinations thereof.

5. The process of claim 1 wherein said phase change material comprises a chalcogenide.

6. The process of claim 1 wherein said phase change material comprises selenium (Se).

7. The process of claim 1 wherein said phase change material comprises tellurium (Te).

8. The process of claim 1 wherein said phase change material comprises 2 to about 4 component combinations of germanium (Ge), antimony (Sb), bismuth (Bi), palladium (Pd), tin (Sn), silver (Ag), arsenic (As), silicon (Si), phosphorus (P), nitrogen (N), indium (In), and a chalcogen.

9. The process of claim 8 wherein said phase change material comprises Ge—Sb—Te; As—Sb—Te; As—Ge—Sb—Te; Sn—Sb—Te; Ag—In—Sb—Te; In—Sb—Te.

10. The process of claim 1 wherein said phase change material comprises a layer of a Group VA element, antimony (Sb) and tellurium (Te); a chalcogen, antimony (Sb) and tellurium (Te); a layer of a Group VA element, antimony (Sb) and selenium (Se); or a layer of a chalcogen (with the exception of Se), antimony (Sb) and selenium (Se).

11. A product made by the process of claim 1.

12. A product made by the process of claim 2.

13. A PCM article of manufacture comprising a dielectric,
a via in said dielectric comprising an opening starting at an area on the surface of said dielectric and extending into said dielectric toward and then terminating at an electrode comprising a first electrode in said dielectric;
a spacer layer that extends around and is contiguous with the side walls of said via;
said via being filled with a PCM that is contiguous with said spacer layer;
a PCM cusp at the opening of said via, said cusp extending above the surface of said dielectric;
said PCM cusp being capped with a capping film;
said PCM and said capping film being densified to produce a high density PCM and a high density capping film whereby said high density capping film exerts compressive pressure on said high density PCM in a direction toward said first electrode to enhance electrical contact between said PCM and said first electrode.

14. The article of manufacture of claim 13 further comprising a dielectric layer having said capping film and said cusp removed to leave an area of exposed high density PCM at said via opening in said dielectric, a second electrode on said exposed high density PCM in said dielectric, and a TEC layer over said second electrode and said dielectric adjacent said second electrode.

15. The article of manufacture of claim 13 wherein said spacer layer is selected from one of SiO, SiN, SiCOH, TiO₂ and Ta₂Oₛ, and combinations thereof.

16. The article of manufacture of claim 13 wherein said phase change material comprises a chalcogenide.

17. The article of manufacture of claim 13 wherein said phase change material comprises selenium (Se).

18. The article of manufacture of claim 13 wherein said phase change material comprises tellurium (Te).

19. The article of manufacture of claim 13 wherein said phase change material comprises 2 to about 4 component combinations of germanium (Ge), antimony (Sb), bismuth (Bi), palladium (Pd), tin (Sn), silver (Ag), arsenic (As), silicon (Si), phosphorus (P), indium (In), nitrogen (N) and a chalcogen.

20. The article of manufacture of claim 13 wherein said phase change material comprises Ge—Sb—Te; As—Sb—Te; As—Ge—Sb—Te; Sn—Sb—Te; Ag—In—Sb—Te; In—Sb—Te.

21. The article of manufacture of claim 13 wherein said phase change material comprises a Group VA element, antimony (Sb) and tellurium (Te); a chalcogen (with the exception of Te), antimony (Sb) and tellurium (Te); a Group VA element, antimony (Sb) and selenium (Se); or a chalcogen (with the exception of Se), antimony (Sb) and selenium (Se).
